(19) United States
(12) Patent Application Publication
(10) Pub. No.: US 2010/0239751 A1
(43) Pub. Date: Sep. 23, 2010

(54) Sea of Pillars

(75) Inventor: Louis Regniere, Cary, NC (US)

Correspondence Address: STERNE, KESSLER, GOLDSTEIN & FOX P.L.L.C., 1100 NEW YORK AVENUE, N.W., WASHINGTON, DC, 20005, US

(73) Assignee: Sonavation, Inc., Palm Beach Gardens, FL (US)

(21) Appl. No.: 12/728,918

(22) Filed: Mar. 22, 2010

Related U.S. Application Data
(60) Provisional application No. 61/162,512, filed on Mar. 23, 2009.

(51) Int. Cl. H01L 41/22

(52) U.S. Cl. 427/100

(57) ABSTRACT

Provided is a method for manufacturing multiple devices on a single piezoelectric composite substrate. The piezoelectric composite substrate is significantly larger than a size required for a single device, thus multiple sensors can be simultaneously fabricated from the same piezoelectric composite substrate.

### CROSS REFERENCE TO RELATED APPLICATIONS

The present application claims the benefit of U.S. Provisional Patent Application No. 61/162,512, filed on Mar. 23, 2009, entitled “Sea of Pillars”, which is incorporated herein by reference in its entirety.

### BACKGROUND OF THE INVENTION

1. Field of the Invention

The present invention relates to biometric sensors and sensor manufacturing techniques. More specifically, the present invention relates to ultrasound sensors having a piezoelectric composite substrate.

2. Related Art

In the field of biometric image analysis, traditional techniques sample an image, such as a fingerprint, as the image is sensed by a sensing mechanism. This sensing mechanism, such as a pressure-sensitive piezoelectric fingerprint sensor, captures images of the fingerprint. Ridges and valleys of the fingerprint vary pressure on different parts of an array of piezoelectric pillars within the piezoelectric sensor to form light and dark portions of the captured image.

Conventional biometric sensors suffer from many drawbacks. For example, conventional biometric sensor designs require manufacturing only one sensor at a time. Further, each conventional biometric sensor design requires a corresponding piezoelectric pillar array design that is proprietary to that specific biometric sensor design. Therefore, conventional sensor manufacturing techniques are inflexible. Conventional biometric sensor manufacturing methods also require manufacturing one sensor at a time by using a small PZT substrate. This leads to wasted materials, non-homogeneity, wasted fabrication capacity, and unnecessary production costs.

### SUMMARY OF THE INVENTION

In light of the problems noted above in the conventional approaches, what is needed is a biometric sensor and a biometric sensor manufacturing technique that mitigates the problems noted above.

The present invention is directed to a method for manufacturing multiple biometric sensors from one piezoelectric composite substrate. The piezoelectric composite substrate is significantly larger than a maximum size required for a single sensor, thus an economy of scale is provided because multiple sensors can be simultaneously fabricated from the same piezoelectric composite substrate. Further, an economy of scale also is provided because a plurality of different biometric sensors with different interconnections among pillars in their respective array can be fabricated from one piezoelectric composite substrate.

When using the techniques described herein, multiple designs and types of sensors, such as swipe sensors and touch sensors (also known as static sensors) can be fabricated from the same piezoelectric composite substrate. When the same piezoelectric composite substrate can be used for multiple sensor designs, only the lithographic elements change between different designs of sensors. This permits manufacturing a plurality of piezoelectric composite substrates, each having their own respective piezoelectric pillar array, that are fabricated with the same piezoelectric pillar array design. The plurality of piezoelectric composite substrates can then be stockpiled and used later during manufacturing of sensors having different designs. The stockpile of piezoelectric composite substrates can then be used to fabricate sensors having a pattern of interconnects that are determined at a time after establishment of the stockpile.

Further embodiments, features, and advantages of the present invention, as well as the structure and operation of the various embodiments of the present invention are described in detail below with reference to accompanying drawings.

### BRIEF DESCRIPTION OF THE DRAWINGS/FIGURES

The accompanying drawings illustrate the present invention and, together with the description, further serve to explain the principles of the invention and to enable one skilled in the pertinent art to make and use the invention.

FIG. 1 is an illustration of a conventional biometric sensing device fabricated using conventional methods.

FIG. 2 is an illustration of a conventional biometric sensing device fabricated using conventional methods.

FIG. 3 is an illustration of an exemplary array of piezoelectric pillars that is part of a piezoelectric composite substrate.

FIG. 4 is an illustration of an exemplary array of piezoelectric pillars having interconnects and contacts on a first side of a piezoelectric composite substrate.

FIG. 5 is an illustration of an exemplary array of piezoelectric pillars having interconnects and contacts on a second side of the piezoelectric composite substrate of FIG. 4.

FIG. 6 is an illustration of an exemplary plurality of biometric sensors formed from the exemplary array of piezoelectric pillars having interconnects and contacts of both FIGS. 5 and 6.

FIG. 7A is an illustration of an exemplary plurality of biometric sensors.

FIG. 7B is an illustration of an exemplary cross-section of an exemplary biometric sensor.

FIG. 8 is an illustration of an different exemplary array of piezoelectric pillars having interconnects and contacts on a first side of a piezoelectric composite substrate.

FIG. 9 is an illustration of an different exemplary array of piezoelectric pillars having interconnects and contacts on a second side of a piezoelectric composite substrate.

FIG. 10 is a flowchart of an exemplary method for manufacturing a plurality of devices on a single piezoelectric composite substrate.

FIG. 11 is a flowchart of an exemplary method for manufacturing a plurality of devices on a single piezoelectric composite substrate.

FIG. 12 is a flowchart of an exemplary method for manufacturing a 1:3 composite piezoelectric substrate.

In the drawings, like reference numbers generally indicate identical, functionally similar, and/or structurally similar elements. The drawing in which an element first appears is usually indicated by the leftmost digit(s) in the reference number. Unless otherwise indicated, the figures are not drawn to scale.

### DETAILED DESCRIPTION OF THE INVENTION

This specification discloses one or more embodiments that incorporate the features of this invention. The embodiment(s) described, and references in the specification to “one embodiment”, “an embodiment”, “an example embodiment”, etc., indicate that the embodiment(s) described may include a particular feature, structure, or characteristic, but every embodiment may not necessarily include the particular feature, structure, or characteristic. Moreover, such phrases are not necessarily referring to the same embodiment. Furthermore, when a particular feature, structure, or characteristic is described in connection with an embodiment, it is submitted that it is within the knowledge of one skilled in the art to effect such feature, structure, or characteristic in connection with other embodiments whether or not explicitly described.

### Overview

Embodiments provide methods and apparatus for fabricating a piezoelectric sensor. The methods described herein mitigate problems of mass production, wasted materials, wasted fabrication capacity, and high production costs. The methods also enable an economy of scale that enables stockpiling and reduces both costs and turn-around time for producing a customized biometric device. Other advantages include material homogeneity among multiple sensors produced from a common substrate, as well as producing a substrate that can be used with different sensor contact arrangements.

### Exemplary Apparatus

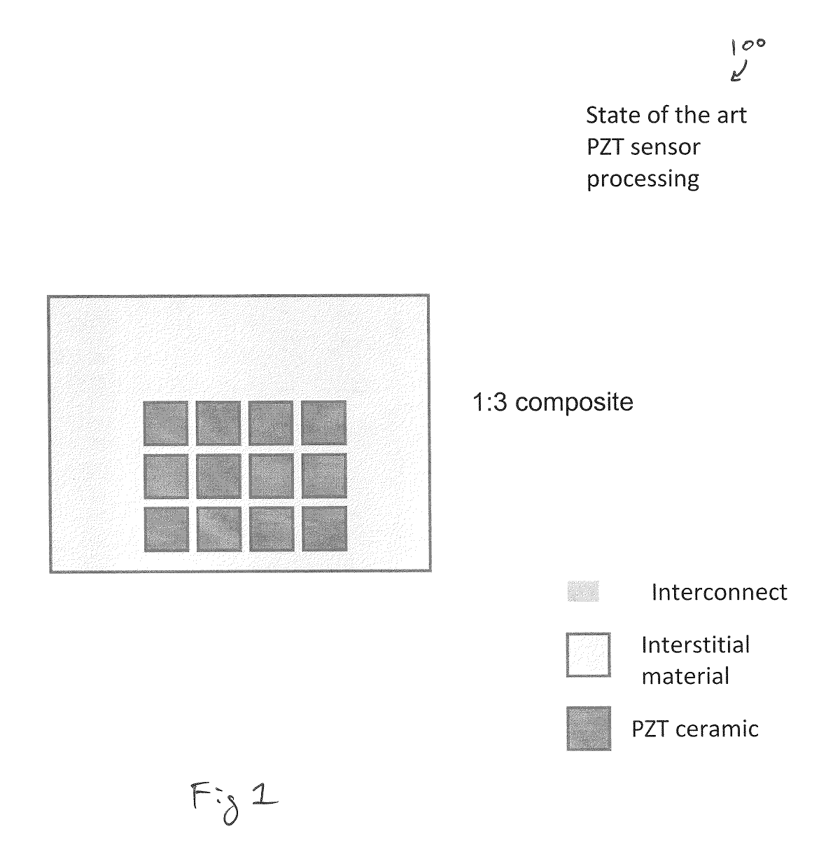

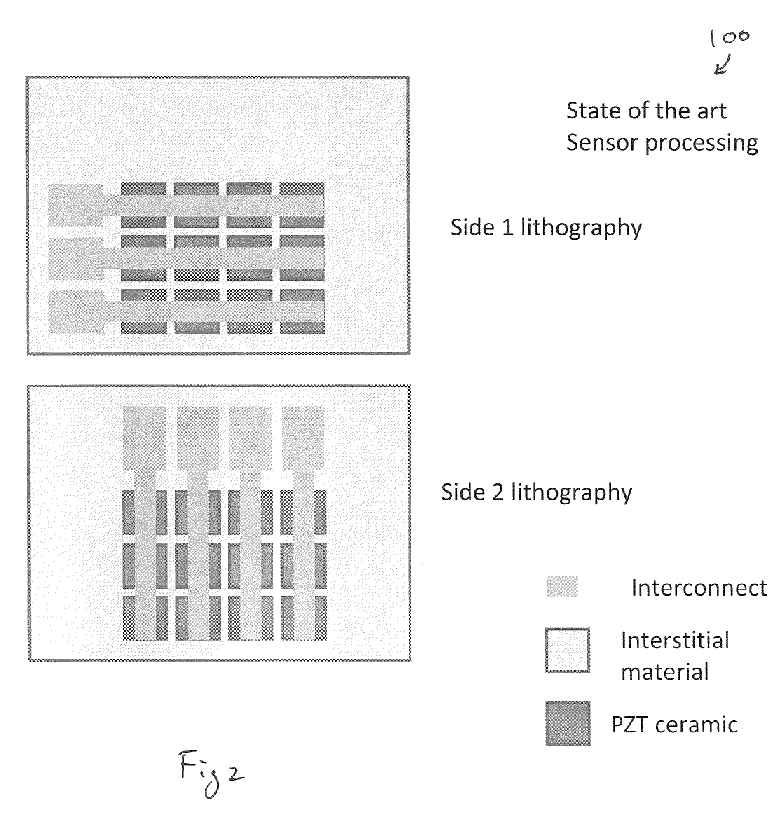

FIGS. 1 and 2 are illustrations of a conventional biometric sensing device 100 fabricated using conventional methods.

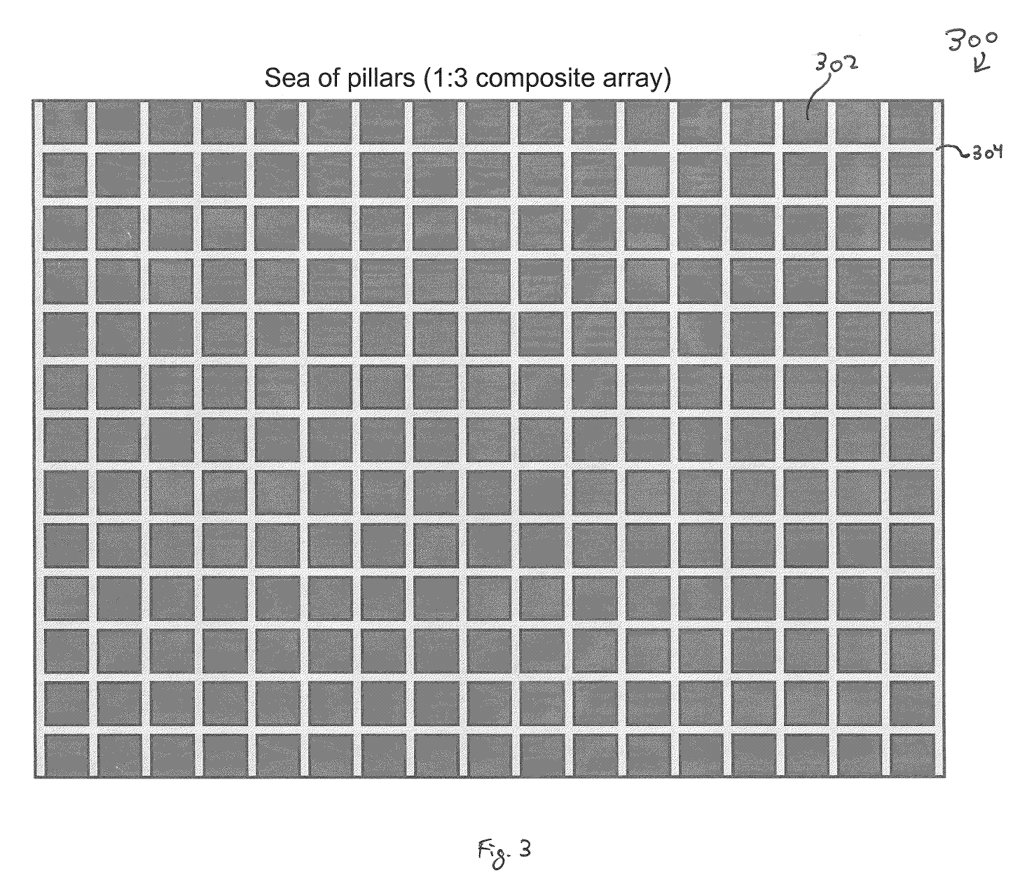

FIG. 3 is an illustration of an exemplary array of piezoelectric pillars 302 embedded in an interstitial material 304 forming a piezoelectric composite substrate 300. Examples of the piezoelectric composite substrate 300 include a 3:1 composite substrate and a 2:2 composite substrate. Though FIG. 3 illustrates an array having dimensions of seventeen by thirteen pillars, the array of piezoelectric pillars 302 is not limited to these dimensions. By way of example, the array of piezoelectric pillars 302 can be comprised of lead zirconate titanate, also known as PZT. The present invention, however, is not limited to PZT. FIG. 3 shows a first step of manufacturing a biometric sensor where multiple biometric sensors are simultaneously manufactured with no more operations than those required to create one conventional biometric sensor. For example, using the methods described herein, one hundred sensors can be fabricated in the time it takes to fabricate one sensor using conventional methods.

Also, the number of pillars in the array of piezoelectric pillars 302 can be a number that is greater than that required for fabrication of a plurality of sensors. Thus, a plurality of sensors can be fabricated simultaneously from the array of piezoelectric pillars 302 to provide an economy of scale which mitigates the problems of the conventional fabrication methods noted herein.

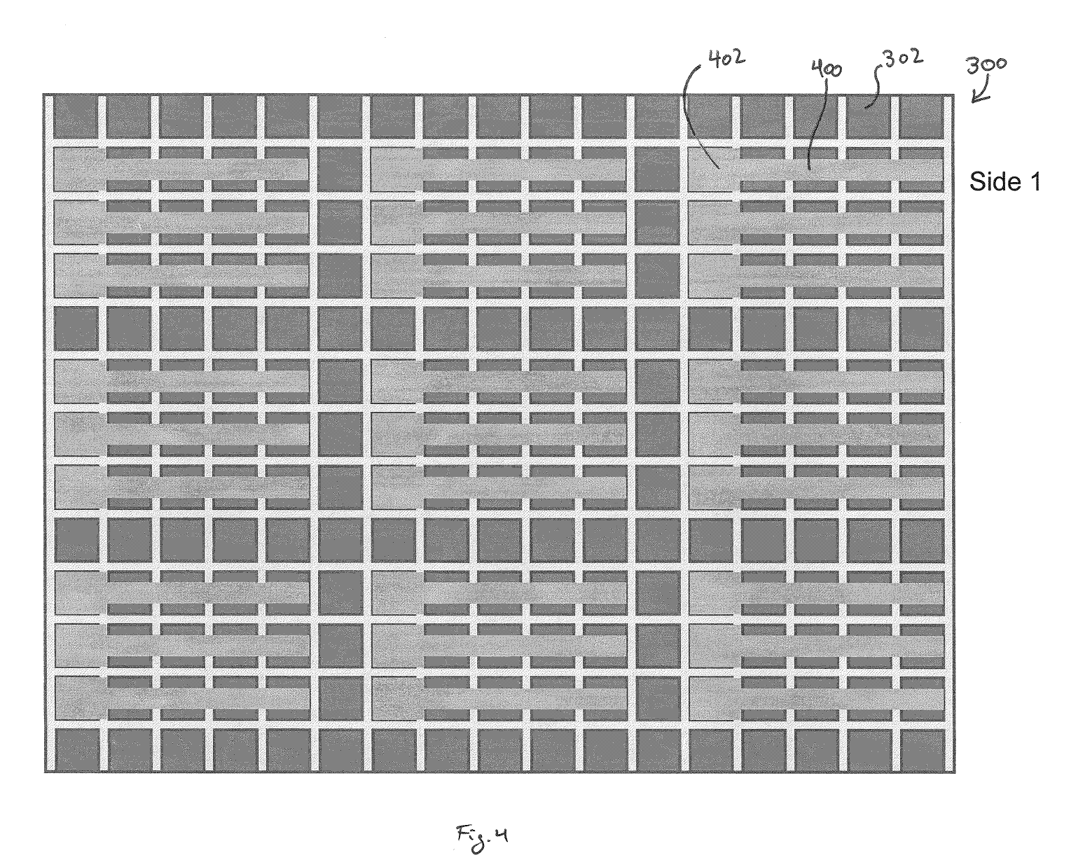

FIG. 4 is an illustration of the array of piezoelectric pillars 302 having interconnects and contacts on a first side of the piezoelectric composite substrate 300, and shows a second step of manufacturing a biometric sensor . The piezoelectric composite substrate 300 includes a first pattern of first interconnects 400 coupled to first contacts 402 deposited on the piezoelectric composite substrate 300 using a lithographic technique. The first interconnects 400 and the first contacts 402 are coupled to either a row or column of the array of piezoelectric pillars 302. In a further example, the first interconnects 400 and the first contacts 402 are each coupled to at least one respective piezoelectric pillar in the array of piezoelectric pillars 302. FIG. 4 also illustrates a quantity of nine of the first exemplary patterns of first interconnects 400 coupled to first contacts 402 which can be used to fabricate a biometric sensor, such as a swipe-type sensor or a static-type sensor. The present invention is not limited to nine exemplary interconnect patterns.

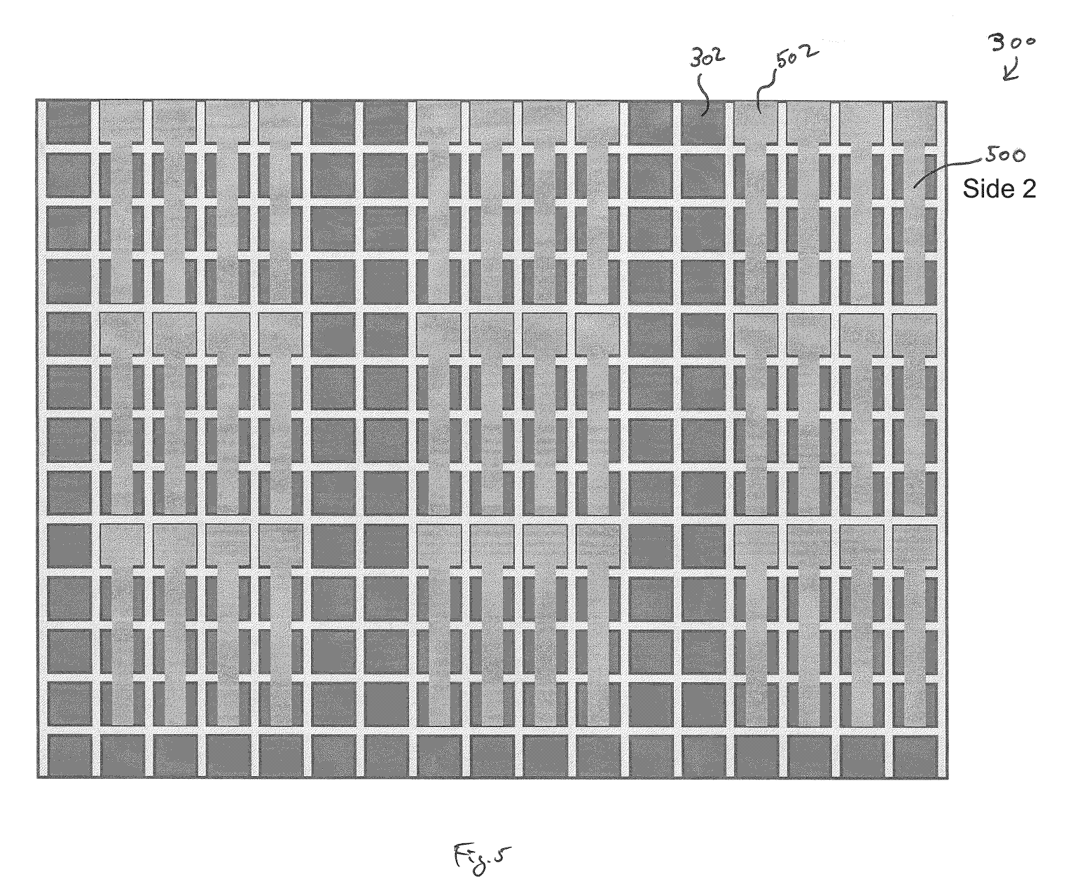

FIG. 5 is an illustration of the array of piezoelectric pillars 302 having a second pattern of second interconnects 500 coupled to second contacts 502 and deposited on the piezoelectric composite substrate 300 using a lithographic technique. The second interconnects 500 and the second contacts 502 are coupled to either a row or column of the array of piezoelectric pillars 302 in the piezoelectric composite substrate 300. In a further example, the second interconnects 500 and the second contacts 502 are each coupled to at least one respective piezoelectric pillar in the array of piezoelectric pillars 302. The second pattern of second interconnects 500 and second contacts 502 shown in FIG. 5 are on a side of the piezoelectric composite substrate 300 opposite that of the first pattern of first interconnects 400 and first contacts 402 illustrated in FIG. 4. FIG. 5 shows a third step of manufacturing a biometric sensor.

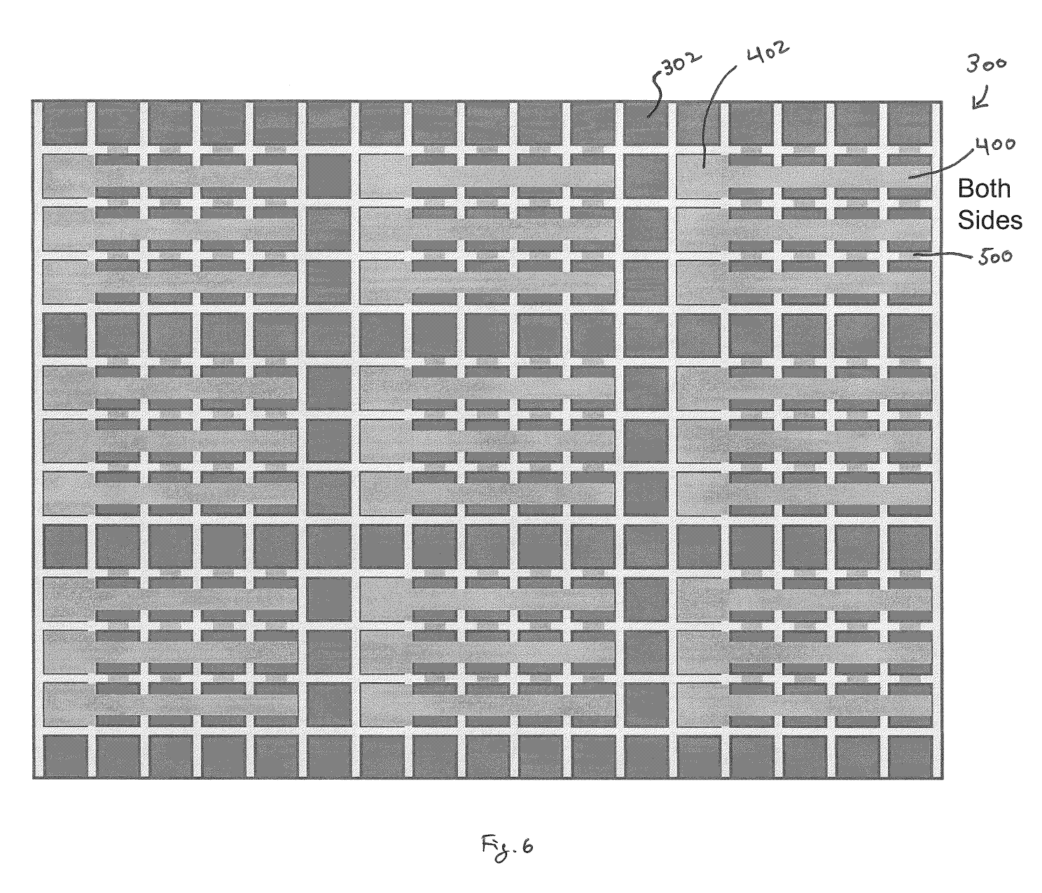

FIG. 6 is an illustration of nine biometric sensors formed from the array of piezoelectric pillars 302. FIG. 6 shows the first pattern of the first interconnects 400, along with the first contacts 402, as well as the second pattern of the second interconnects 500, along with the second contacts 502. In FIG. 6, the first interconnects 400 are located on a first side of the piezoelectric composite substrate 300 and the second interconnects 500 are located on a second side of the piezoelectric composite substrate 300. The first pattern of first interconnects 400 and second pattern of second interconnects 500 are deposited on the piezoelectric composite substrate 300.

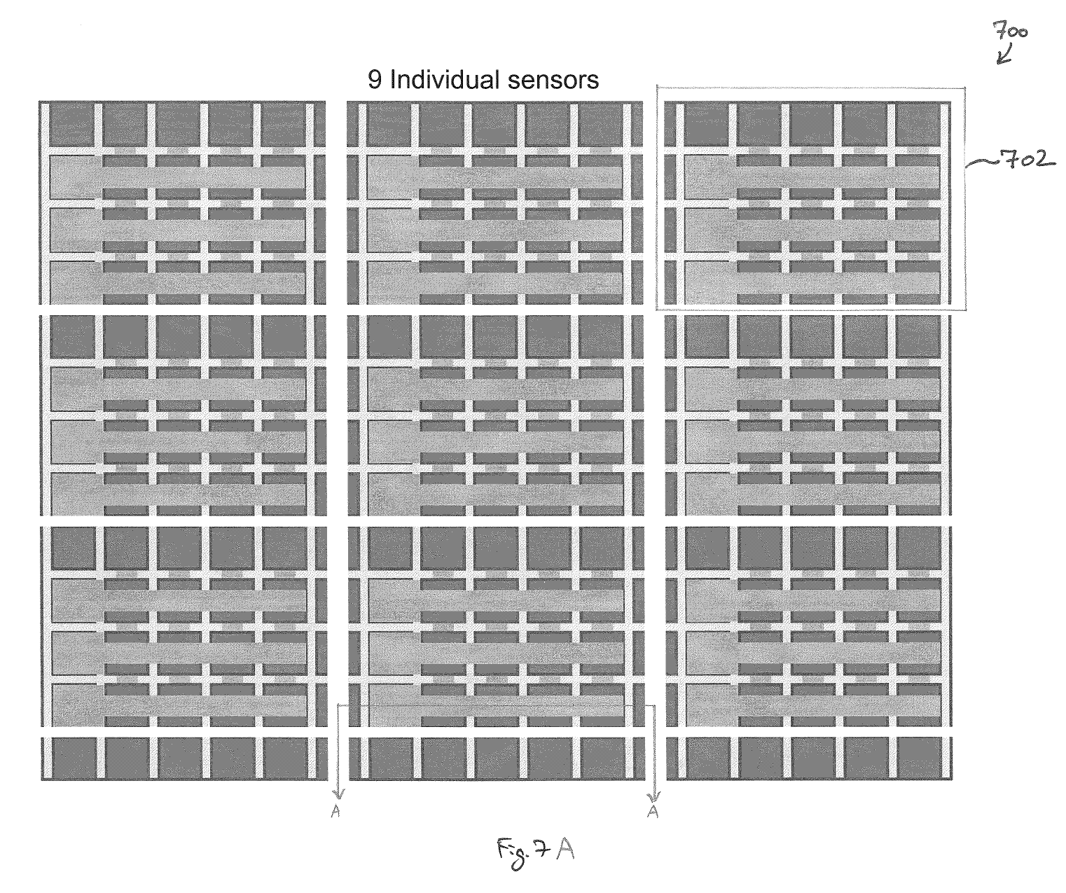

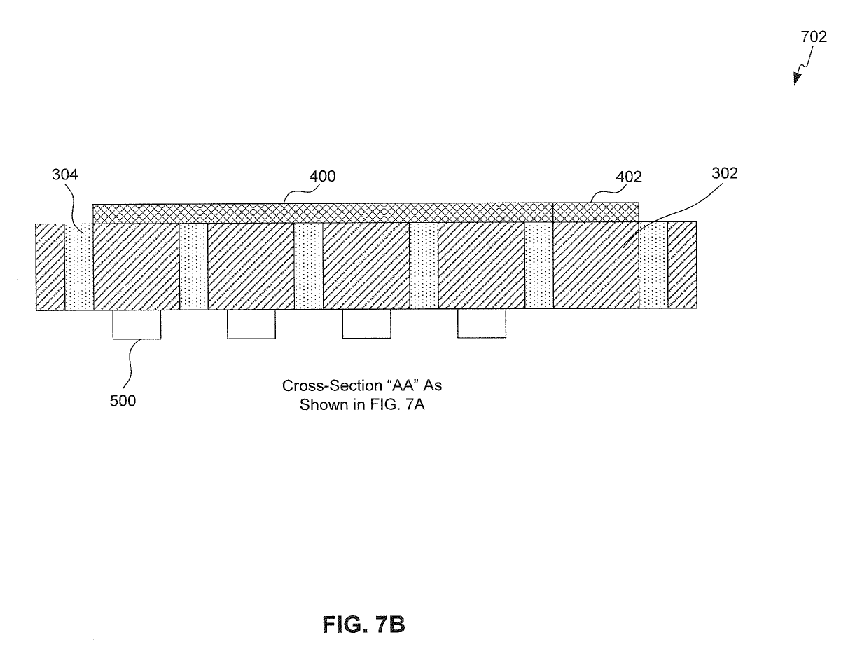

FIG. 7A is an illustration of a plurality of biometric sensors 700 fabricated from the piezoelectric composite substrate 300 and shows a fourth step of manufacturing a biometric sensor. In the illustration of FIG. 7A, the piezoelectric composite substrate 300 is diced to singulate each sensor, such as sensor 702, from the piezoelectric composite substrate 300. Cross section “AA” of FIG. 7A is illustrated in detail in FIG. 7B.

FIG. 7B is an illustration of an exemplary cross-section of the sensor 702. The cross section illustrated in FIG. 7B is cross section “AA” shown in FIG. 7A.

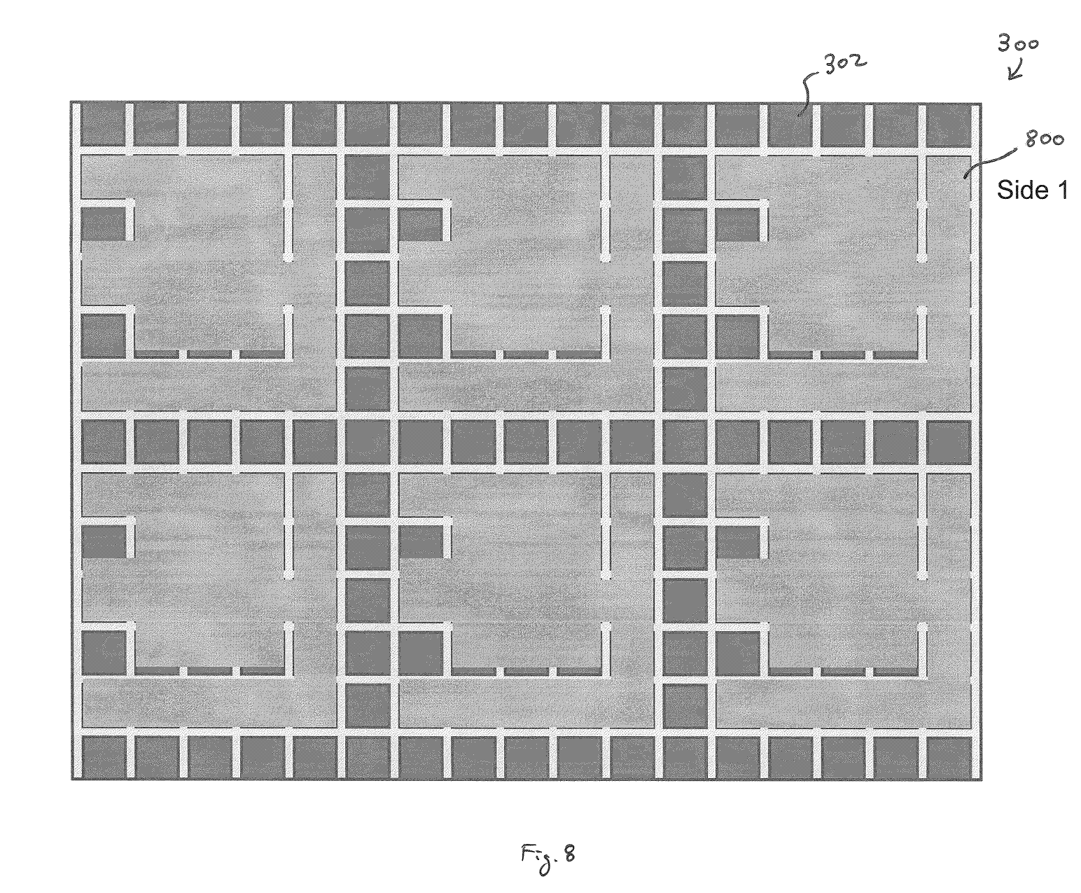

FIG. 8 is an illustration of the piezoelectric composite substrate 300 having deposited upon it a third pattern 800 of interconnects and contacts that is different from the first interconnects 400 and the first contacts 402 illustrated in FIG. 4. By way of example, FIG. 8 illustrates a quantity of six of the third pattern 800, which each can be used to fabricate a biometric sensor such as a swipe-type sensor or a static-type sensor.

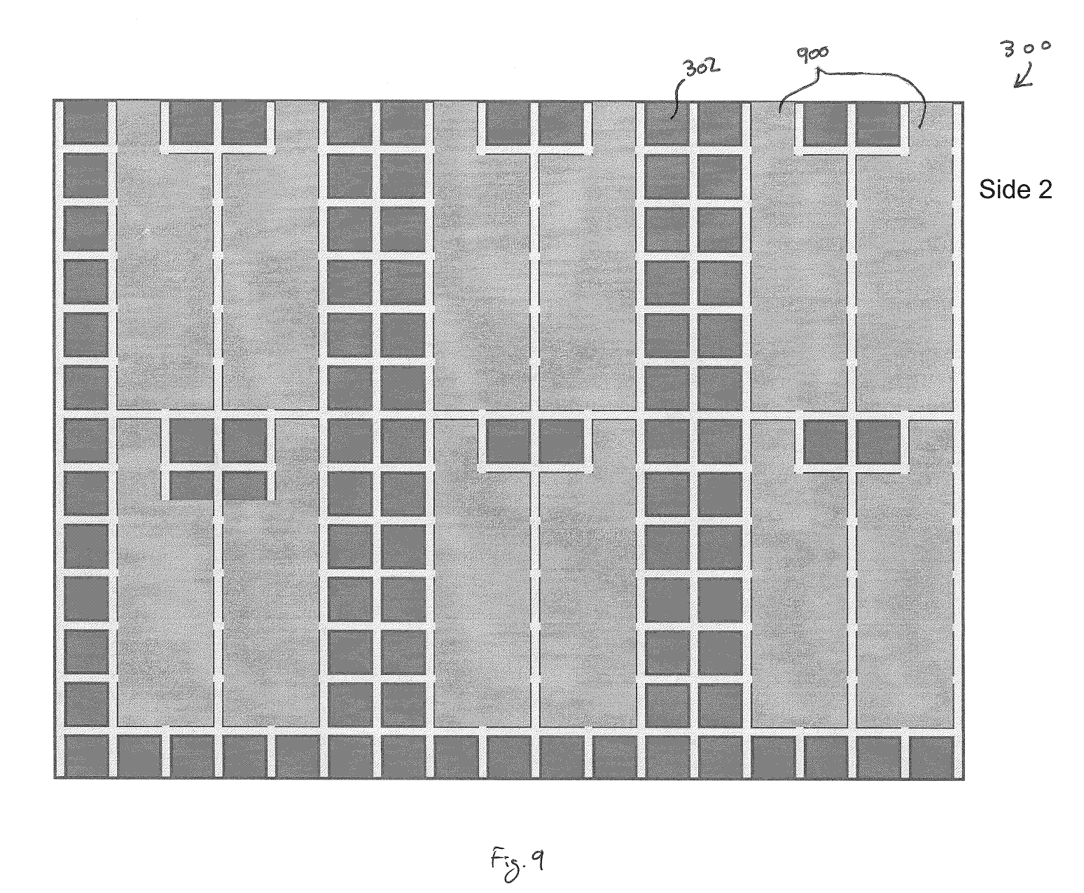

FIG. 9 is an illustration of the piezoelectric composite substrate 300 having deposited upon it a fourth pattern 900 of interconnects and contacts that is different from the second interconnects 500 and the second contacts 502 illustrated in FIG. 5. FIG. 9 illustrates a quantity of six of the exemplary fourth pattern 900 which can be used to fabricate a biometric sensor such as a swipe-type sensor or a static-type sensor. The third pattern 800 can be deposited on a first side of the piezoelectric composite substrate 300 and the fourth pattern 900 can be deposited on a second side of the piezoelectric composite substrate 300.

When using the techniques described herein, multiple designs of sensors, such as swipe sensors and touch sensors (also known as a static sensor) can be fabricated from the same piezoelectric composite substrate 300. Only the lithographic elements, for example, an interconnect between pillars and a contact, change between different sensor designs because the same piezoelectric composite substrate 300 can be used for manufacturing different sensors having different sensor designs. This permits manufacturing a plurality of the sensors on a respective plurality of substrates, such as the piezoelectric composite substrate 300, which can then be stockpiled and used later during manufacturing of different designs of sensors. The stockpile of substrates can also be used to fabricate sensors having a pattern of interconnects that are determined at a time after establishment of the stockpile. Exemplary manufacturing methods are now described.

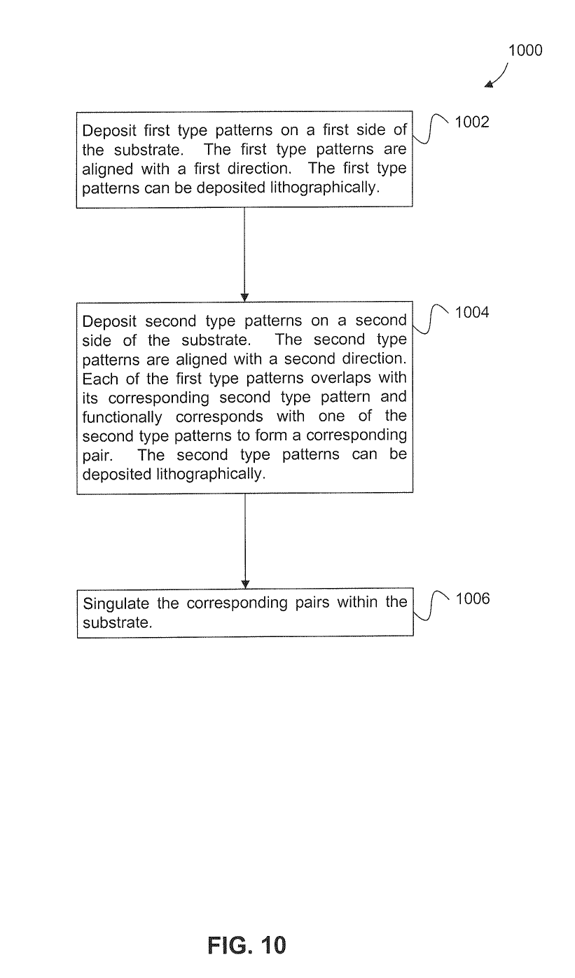

FIG. 10 is an illustration of an exemplary manufacturing method 1000 for near simultaneously creating multiple devices on a single piezoelectric composite substrate. For example, the manufacturing method 1000 can be used to fabricate a swipe-type sensor or a static-type sensor on the piezoelectric composite substrate 300.

In step 1002, a first type pattern is deposited, for on a first side of the substrate.

The first type patterns are aligned with a first direction. The first type patterns can be deposited lithographically.

In step 1004, a second type pattern is deposited on a second side of the substrate.

The second type patterns are aligned with a second direction. Each of the first type patterns overlaps with its corresponding second type pattern and functionally corresponds with one of the second type patterns to form a corresponding pair, such as one of the multiple devices. As a further example, each corresponding pair can be a biometric sensor. The second type patterns can be deposited lithographically. The functional correspondence can include an electrical connection.

In step 1004, the corresponding pairs are singulated within the substrate. Singulation separates a plurality of devices into at least two devices.

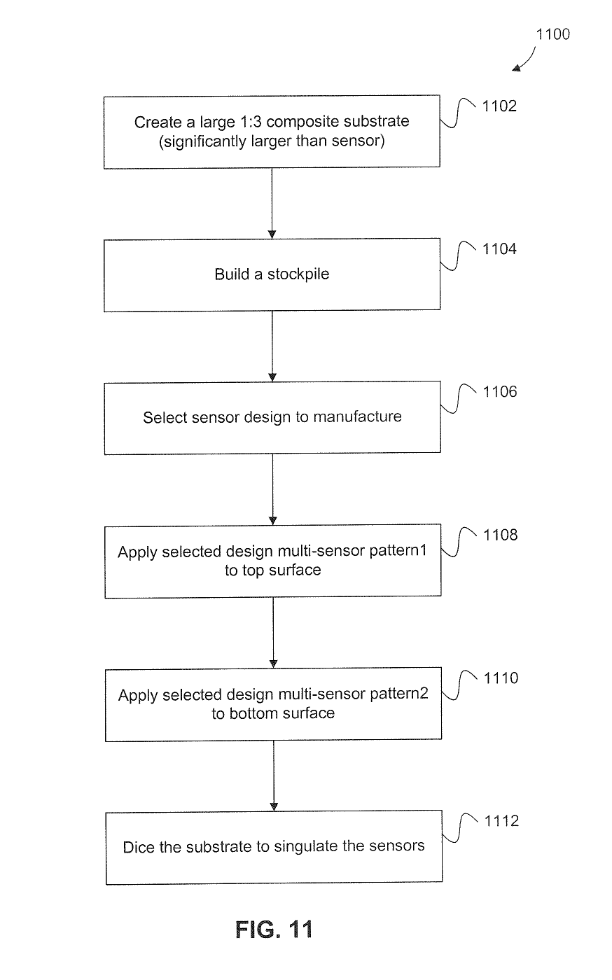

FIG. 11 is an illustration of an exemplary manufacturing method 1100 for near simultaneously creating multiple devices on a single piezoelectric composite substrate. For example, the manufacturing method 1100 can be used to fabricate a swipe-type sensor or a static-type sensor on the piezoelectric composite substrate 300.

In step 1102, a large 1:3 composite substrate, significantly larger than a sensor, is created. In step 1104, the substrates fabricated in step 1102 are stockpiled. In step 1106, a sensor design to manufacture is selected. In step 1108, a first pattern of the selected design is applied to the top surface of a substrate. In step 1110, a second pattern of the selected design is applied to the bottom surface of the substrate. In step 1112, the substrate is diced to singulate the sensors.

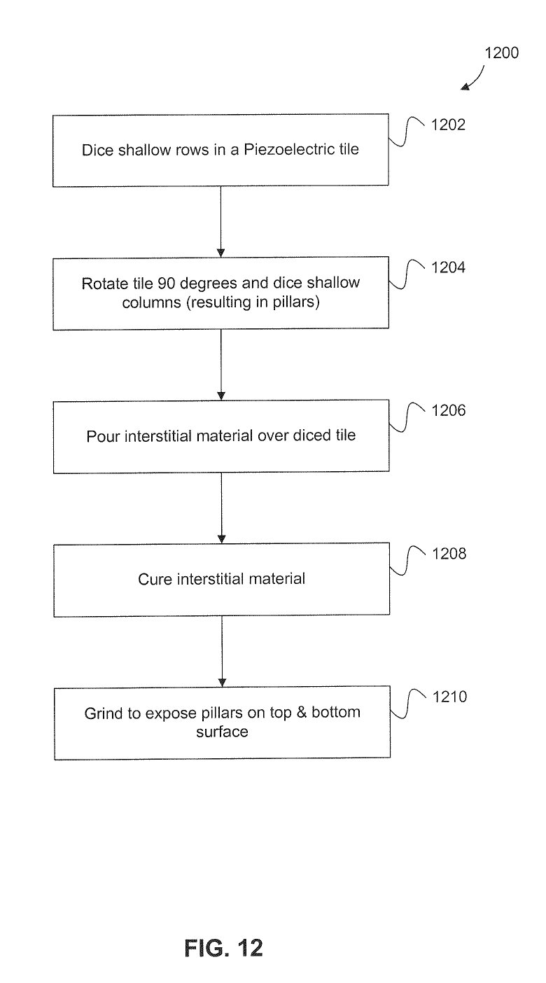

FIG. 12 is a flowchart of a state of the art method for manufacturing a 1:3 composite piezoelectric substrate. In step 1202, shallow rows are diced in a piezoelectric tile. In step 1204, the tile is rotated 90 degrees and shallow columns are diced, resulting in pillars. In step 1206, interstitial material is poured over the diced tile. In step 1208, the interstitial material is cured. In step 1210, the tile is ground to expose pillars on the top and bottom surface of the tile.

### Conclusion

Examples that incorporate the features of this invention are described herein.

These examples are described for illustrative purposes only, and are not limiting. Other embodiments are possible. Such other embodiments will be apparent to persons skilled in the relevant art(s) based on the teachings contained herein. Thus, the breadth and scope of the present invention is not limited by any of the above-described exemplary embodiments, but must be defined only in accordance with the following claims and their equivalents.

The description fully reveals the nature of the invention that others may, by applying knowledge within the skill of the art, readily modify and/or adapt for various applications the exemplary embodiments, without undue experimentation, and without departing from the general concept of the present invention. Therefore, such adaptations and modifications are intended to be within the meaning and range of equivalents of the disclosed embodiments, based on the teaching and guidance presented herein. It is to be understood that phraseology and terminology herein is for the purpose of description and not for limitation, such that the terminology and phraseology of the present specification is to be interpreted by the skilled artisan in light of the teachings and guidance herein.

What I claim is:

1. A method for near simultaneously creating multiple devices on a single piezoelectric composite substrate, comprising:
depositing first type patterns on a first side of the substrate, the first type patterns being aligned with a first direction;
depositing second type patterns on a second side of the substrate, the second type patterns being aligned with a second direction;
wherein each of the first type patterns functionally corresponds with one of the second type patterns to form a corresponding pair; and
singulating the corresponding pairs within the substrate.

2. The method of claim 1, wherein the first type patterns are deposited lithographically.

3. The method of claim 1, wherein the second type patterns are deposited lithographically.

4. The method of claim 1, wherein each of the first type patterns overlaps with its corresponding second type pattern.

5. The method of claim 1, wherein the functional correspondence includes an electrical connection.

6. The method of claim 1, wherein each corresponding pair represents one of the multiple devices.

7. The method of claim 1, wherein each corresponding pair represents a biometric sensor.
